(19) United States
(12) Patent Application Publication
(10) Pub. No.: US 2011/0132459 A1
(43) Pub. Date: Jun. 9, 2011

(54) TRANSPARENT SOLAR CELL SUPERSTRATE

(76) Inventor: Chad Wiltsie Carter, Toledo, OH (US)

(21) Appl. No.: 12/964,501

(22) Filed: Dec. 9, 2010

Related U.S. Application Data
(60) Provisional application No. 61/267,873, filed on Dec. 9, 2009.

(51) Int. Cl. H01L 31/0232

(52) U.S. Cl. 136/259

(57) ABSTRACT

A transparent superstrate for use with solar cells is disclosed. The superstrate has a transparent matrix and a plurality of transparent filler bodies. The transparent filler bodies are embedded in the transparent matrix.

### RELATED APPLICATION

This application is claiming the benefit, under 35 U.S.C. 119(e), of the provisional application which was granted Ser. No. 61/267,873 filed on Dec. 9, 2009 under 35 U.S.C. 111(b). This provisional application is hereby incorporated by reference.

### BACKGROUND OF THE INVENTION

Photovoltaic (PV) modules may be constructed by electrically connecting one or more solar cells in series and encapsulating the cells. Thin-film solar cells are typically deposited on a superstrate or a substrate (hereinafter “superstrate”) prior to being encapsulated. The superstrate may be flexible, semi-rigid, or rigid. Rigid superstrates are advantageous because of the ease in which the superstrate can be handled before, during, and after solar cell deposition. However, being deposited on rigid superstrates limits the applications in which the solar cell may be employed. Solar cells deposited on a flexible superstrate can be utilized in a wide range of applications. However, solar cells deposited on a flexible substrate are more susceptible to handling issues.

The present invention relates to an improved solar cell superstrate which combines the above-described advantages of rigid and flexible superstrates. More particularly, the invention relates to an improved superstrate that also has a high degree of visible light transmission.

### BRIEF SUMMARY OF THE INVENTION

A transparent solar cell superstrate is provided. The transparent solar cell superstrate comprises a transparent matrix. The transparent solar cell superstrate also comprises a plurality of transparent filler bodies embedded in the transparent matrix.

### BRIEF DESCRIPTION OF THE DRAWINGS

FIG. 1 is a top view of an embodiment of the present invention;

FIG. 2a is a cross-sectional view of an embodiment of the present invention;

FIG. 2b is a cross-sectional view of an embodiment of the present invention;

FIG. 2c is a cross-sectional view of an embodiment of the present invention;

FIG. 3 is a cross-sectional view of an embodiment of the present invention; and

FIG. 4 is a comparison of the visible light transmission of an embodiment of the present invention with known superstrates.

### DETAILED DESCRIPTION OF THE PREFERRED EMBODIMENT(S)

It is to be understood that the invention may assume various alternative configurations and step sequences, except where expressly stated to the contrary. It should also be appreciated that the specific embodiments and processes illustrated in and described in the following specification are simply exemplary embodiments of the inventive concepts defined in the appended claims. For example, although the present invention will be described in connection with solar cell superstrates having at least one cadmium telluride (CdTe) single junction (SJ) the present invention is not so limited. As such, the present invention may also be applied to solar cells comprising at least one SJ of (e.g.) CdZnTe or other cadmium telluride II VI materials, amorphous silicon (a-Si), amorphous silicon germanium (a-SiGe), microcrystalline silicon (mc-Si), nanocrystalline silicon (nc-Si), CISe₂, CIGS or another chalcopyrite material and organic and polymer solar cells. Additionally, although the present invention will be described as a superstrate it should be appreciated that it may also be utilized as a substrate.

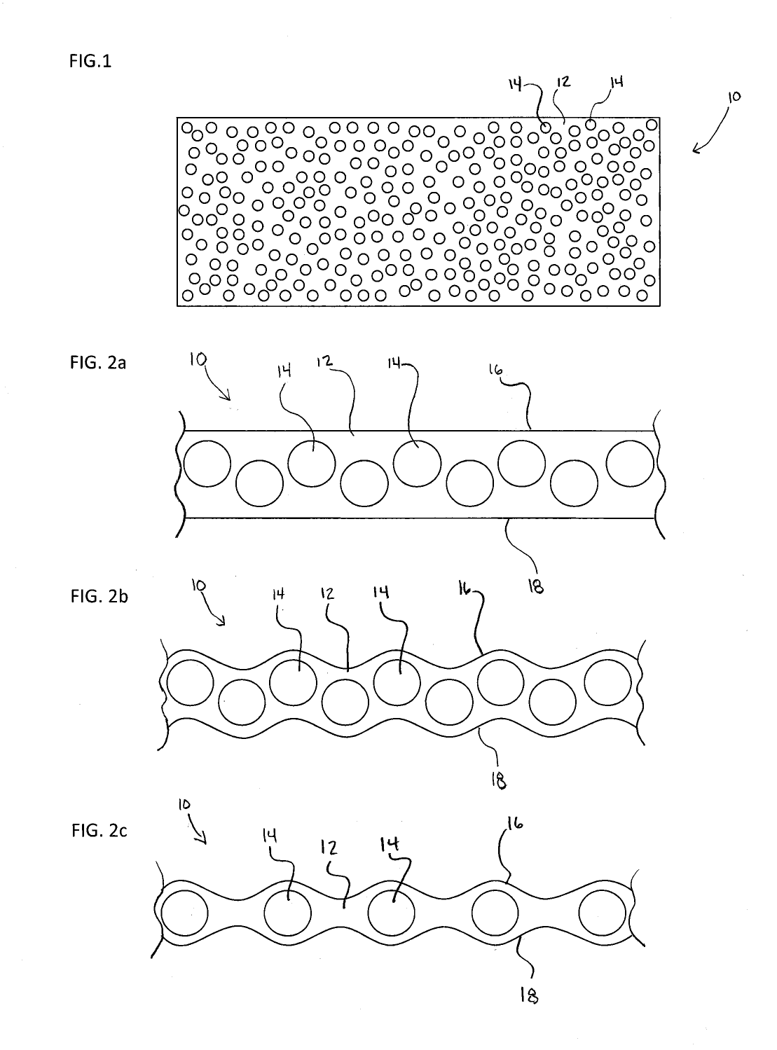

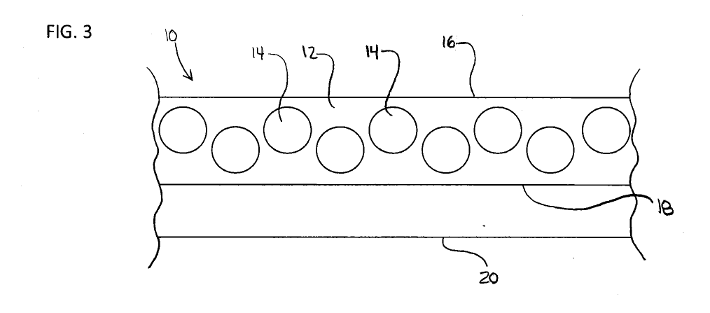

FIGS. 1 and 2a-2c depict embodiments of the superstrate 10 of the present invention.

The superstrate 10 comprises a transparent matrix 12. The transparent matrix 12 is preferably stable, i.e. is not chemically altered and/or does not substantially decompose, at temperatures approximately equal to or greater than 390° C. For instance, when heated to about 390° C. and exposed to CdCl₂, the superstrate 10 loses less than 2% of its mass, loses less than 5% of its visible light transmission, and suffers little loss in mechanical properties when compared with its properties before heating and exposure to CdCl₂. The transparent matrix 12 may be either a thermoset or a thermoplastic transparent matrix. Furthermore, the transparent matrix 12 provides a high visible light transmission, preferably over 50% between 600-900 nanometers of the electromagnetic spectrum.

In an embodiment, the transparent matrix 12 comprises a polyimide material. In this embodiment, the transparent matrix comprises imide monomers. One preferable polyimide material is Kapton® polyimide sold by E.I. du Pont de Nemours and Company. It should be appreciated that other polyimides may be suitable for use in the present invention separately or in combination with each other. In these embodiments, the transparent matrix material is carbon based. However, in other embodiments, the transparent matrix material may be a silicon based material such as a silicon resin.

The superstrate 10 also comprises a plurality of transparent filler bodies 14. The transparent filler bodies 14 are embedded in the transparent matrix 12. In an embodiment, the transparent filler bodies 14 are at least partially covered by the transparent matrix 12. Preferably, the transparent filler bodies 14 are fully covered by the transparent matrix 12. In an embodiment, the transparent filler bodies 14 are composed of glass.

In practice, a solar cell is disposed on at least one surface 16, 18 of the superstrate 10. FIG. 3 depicts an embodiment wherein the superstrate 10 shown in FIG. 2a has a solar cell 20 disposed on its second surface 18. As should be appreciated, the superstrate embodiments shown in FIGS. 2b and 2c may be substituted for the superstrate 10 shown in FIG. 3.

As such, the optical properties, particularly in the wavelength range from 300 nm to 1200 nm, of the superstrate 10 may be selected to enhance solar cell performance. For example, the superstrate 10 may be transparent. In another embodiment, the optical properties of superstrate 10 may be chosen to focus light into or back into a solar cell. In yet another embodiment, the optical properties of the superstrate 10 may be chosen to maximize the collection of light incident from a wide range of angles onto a first surface 16 of the superstrate 10 to deliver light to the solar cell on the second surface 18 of the superstrate 10 or vice versa depending on the location of the solar cell. In these embodiments, the optical properties of superstrate 10 may be provided by selecting a property of the transparent matrix 12, the transparent filler bodies 14, or a combination thereof.

An optical property of particular interest is visible light scattering in and/or through the superstrate 10. In an embodiment, the transparent matrix 12 and the transparent filler bodies 14 may be selected to have substantially similar indices of refraction to minimize light scattering in or through the superstrate 10. In another embodiment, the transparent matrix 12 and the transparent filler bodies 14 may be selected to have substantially different indices of refraction to increase light scattering in or through the superstrate 10. In this embodiment, the transparent matrix 12 has an index of refraction from 1.8-2.0 and the transparent filler bodies 14 have an index of refraction from 1.4-1.6.

In another embodiment, the size of the transparent filler bodies 14 may be selected to provide for increased visible light scattering through the superstrate 10. In this embodiment, the transparent filler bodies 14 may be spherical in shape. As such, in this embodiment, the transparent filler bodies 14 may have diameters of approximately 75 μm. Alternatively, the transparent filler bodies 14 may have diameters of less than 75 μm. In another alternative, the transparent filler bodies 14 have diameters of more than 75 μm, i.e. diameters of approximately 100 μm. It should be appreciated that transparent filler bodies 14 having different diameters may be used separately or in combination within the same superstrate. It should also be appreciated that the present invention is not limited to a particular transparent filler body diameter.

Additionally, the shape of the transparent filler bodies 14 may be selected to provide for increased visible light scattering through the superstrate. As such, in the present invention, the transparent filler bodies 14 are not limited to a particular shape. Thus, the transparent filler bodies 14 may have uniform diameters or may have irregular diameters. In another embodiment, the transparent filler bodies 14 may have substantially smooth surface portions and/or have rough surface portions.

Regardless of their size and/or shape, it is preferred that the transparent matrix 12 covers the transparent filler bodies 14. As depicted in FIG. 2a, the quantity of transparent matrix material may be selected to form a smooth, planar surface either on one or both surfaces 16, 18 of the superstrate 10. However, as depicted in FIGS. 2b and 2c, the quantity of transparent matrix material may be selected so as to create substantial surface roughness on either the first 16, second 18 or both surfaces of the superstrate 10 to produce light scattering. It should also be noted that the size, shape, and loading of the transparent filler bodies 14 may be selected to adjust the roughness of either the first 16, second 18, or both surfaces of the superstrate 10. Superstrate surface roughness not only influences the light scattering properties of the superstrate 10, but roughness may also improve solar cell adhesion onto a surface of the superstrate 10.

Another optical property of interest is visible light transmission through the superstrate 10. The transmission visible light transmission through the superstrate 10 may be improved by using transparent filler bodies 14 selected to have a specific composition. For instance, in an embodiment where the transparent filler bodies 14 are composed of glass, the filler bodies 14 may have a low iron content to minimize light absorption. In another embodiment, the concentration of other materials, such as lead, may also be varied in the transparent filler bodies 14 to increase the visible light transmission properties of the superstrate 10. Additionally, the shape, size, and porosity of the transparent filler bodies 14 can be varied to improve the transmission and the scattering of visible light through the superstrate 10. It should be appreciated that the transparent filler bodies 14 may be comprised of other materials besides glass.

The superstrate 10 of the present invention is more rigid than superstrates comprised solely of a transparent matrix material such as polyimide. Further, the superstrate 10 of the present invention is also more flexible than superstrates comprised solely of transparent filler material such as glass. However, it should be noted that flexibility or the rigidity of the superstrate 10 depends at least in part on the quantity of the transparent matrix material and the concentration of the transparent filler bodies 14 within the superstrate 10.

Superstrate surface roughness not only influences the transmission, refraction, and/or scattering of visible light, but texture may also improve solar cell adhesion onto the superstrate 10. It should therefore be appreciated that the texture of the superstrate 10 may also be varied by the loading of the transparent filler bodies 14. As shown in FIGS. 1 and 2a-2c, the concentration of transparent filler bodies 14 is preferably uniform throughout the transparent matrix 12. However, the superstrate 10 of the present invention is not limited to a particular distribution of filler bodies 14. As shown in FIG. 2c, the transparent filler bodies 14 are embedded in an ordered monolayer by the transparent matrix 12. However, as shown in FIGS. 2a and 2b, the transparent filler bodies 14 need not be embedded by the transparent matrix 12 in an ordered fashion. As such, while the concentration of transparent filler bodies 14 may be uniform, the transparent filler bodies 14 may be randomly dispersed within the superstrate 10 with respect to each other.

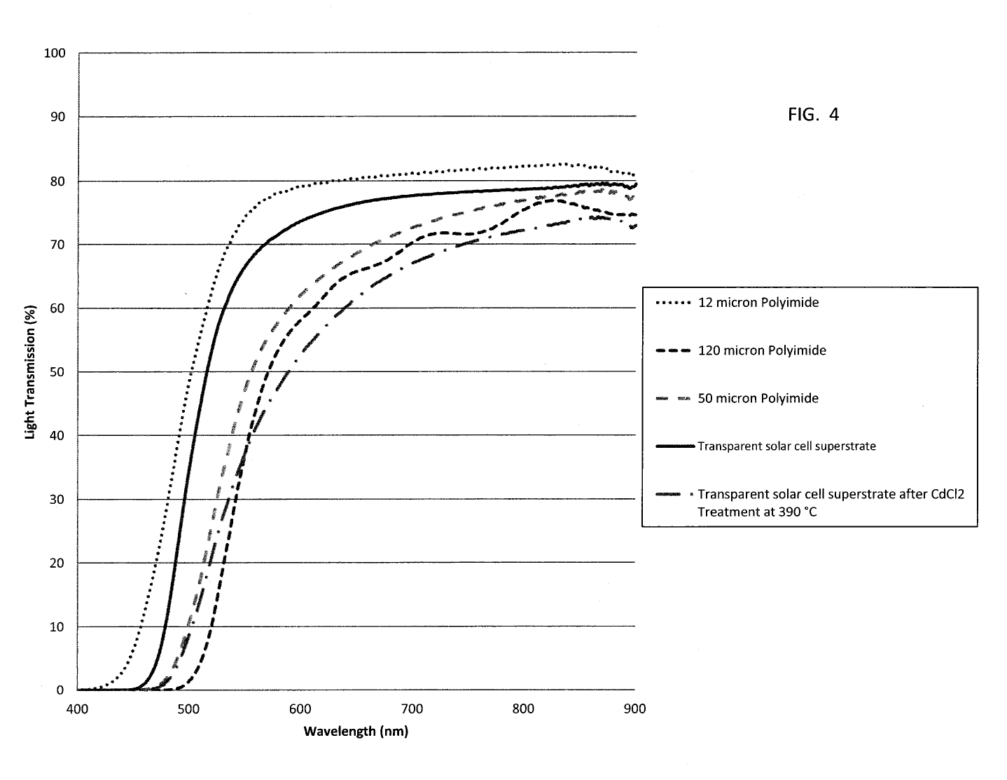

FIG. 4 depicts a comparison of the visible light transmission of an embodiment of the present invention with the visible light transmission of known polyimide superstrates at certain wavelengths of light. The known polyimide superstrates were homogenous. As shown in FIG. 4, transmission data for the polyimide superstrates at various thicknesses is provided. As depicted, as the thickness of the polyimide superstrate increases the transmission of visible light through them decreases.

The superstrate 10 of the present invention utilized for the comparison in FIG. 4, was comprised of a transparent matrix material and a plurality of transparent filler bodies. The transparent matrix material comprised a polyimide. The transparent filler bodies were composed of glass and had diameters of approximately 75 μm. Additionally, the superstrate 10 comprised approximately 10% transparent filler bodies by weight. However, it should be appreciated that the superstrate 10 of the present invention may comprise more than or less than 10% transparent filler bodies. For instance, the superstrate 10 may comprise approximately 45% by weight transparent filler bodies. Thus, the superstrate 10 of the present invention may comprise transparent filler bodies chosen at such a weight percentage of the superstrate 10 so as to increase the rigidity of the superstrate 10, without increasing the overall quantity of the transparent matrix material, and maintain high visible light transmission. As such, the present invention provides a superstrate which is more rigid than and also has a visible light transmission similar to thin polyimide superstrates.

The above detailed description of the present invention is given for explanatory purposes. Thus, it will be apparent to those skilled in the art that numerous changes and modifications can be made without departing from the scope of the invention. Accordingly, the whole of the foregoing description is to be construed in an illustrative and not a limitative sense. Therefore, specific dimensions, directions or other physical characteristics relating to the embodiments disclosed are not to be considered as limiting, unless the claims expressly state otherwise.

What is claimed is:

1. A transparent solar cell superstrate, comprising:
a transparent matrix; and
a plurality of transparent filler bodies embedded in the transparent matrix.

2. The solar cell superstrate of claim 1, wherein the plurality of transparent filler bodies are at least partially or fully covered by the transparent matrix.

3. The solar cell superstrate of claim 1, wherein the plurality of transparent filler bodies are composed of glass and the transparent matrix comprises a polyimide.

4. The solar cell superstrate of claim 1 wherein the superstrate has at least one smooth, planar surface.

5. The solar cell superstrate of claim 1, wherein the superstrate has a surface roughness which produces light scattering from a first surface to a second surface of the superstrate.

6. The solar cell superstrate of claim 1, wherein the transparent matrix and the transparent filler bodies have substantially similar indices of refraction.

7. The solar cell superstrate of claim 1, wherein the transparent matrix and the transparent filler bodies have substantially different indices of refraction.

8. The solar cell superstrate of claim 1, wherein a property of the transparent matrix or the transparent filler bodies is selected so as to modify light scattering or transmission of light, in the wavelength range from 300 nm to 1200 nm, through the superstrate.

9. The solar cell superstrate of claim 1, wherein the transparent matrix and the transparent filler bodies are chosen to increase the rigidity of the superstrate, without increasing the overall quantity of the transparent matrix material, and maintain high visible light transmission.

10. A solar cell, comprising:
a transparent superstrate having a transparent matrix and a plurality of transparent filler bodies embedded in the transparent matrix; and
a solar cell disposed on a surface of the superstrate.
